(19) United States
(12) Patent Application Publication
(10) Pub. No.: US 2012/0186643 A1
(43) Pub. Date: Jul. 26, 2012

(54) COMPOUND SEMICONDUCTOR SOLAR CELLS AND METHODS OF FABRICATING THE SAME

(75) Inventors: William Jo, Seoul (KR); AhReum Jeong, Seoul (KR)

(73) Assignee: EWHA UNIVERSITY-INDUSTRY COLLABORATION FOUNDATION, Seodaemun-gu, Seoul (KR)

(21) Appl. No.: 13/498,254

(22) PCT Filed: Jan. 7, 2010
(86) PCT No.: PCT/KR10/00100

§ 371 Date: Mar. 26, 2012

(30) Foreign Application Priority Data
Oct. 12, 2009 (KR) 10-2009-0096652

(51) Int. Cl. H01L 31/0687; H01L 31/032; H01L 31/18; B82Y 40/00

(52) U.S. Cl. 136/255; 438/72; 257/E31.027; 977/773

(57) ABSTRACT

Provided is a tandem-type compound semiconductor solar cell. The solar cell includes a transparent substrate and a plurality of solar cell layers provided on at least one surface of the transparent substrate. The plurality of solar cell layers respectively includes window layer and light absorbing layer. The light absorbing layer includes Cu(InGa)Se₂ (CIGS) nanoparticles and the light absorbing layers included in the plurality of solar cell layers have different bandgaps due to different gallium (Ga) contents.

### TECHNICAL FIELD

The present invention disclosed herein relates to compound semiconductor solar cells and methods of fabricating the same, and more particularly, to tandem-type compound semiconductor solar cells and methods of fabricating the same.

### BACKGROUND ART

A solar cell or a photovoltaic cell is a key device of a solar power generation system which directly converts sunlight into electricity.

When sunlight having greater energy than the band-gap energy (E_{g}) of a semiconductor is incident on a solar cell manufactured with a semiconductor p-n junction, electron-hole pairs are generated. Since electrons are gathered at an n-layer and holes are gathered at a p-layer due to an electric field formed at the p-n junction, a photovoltage is generated at the p-n junction. At this time, a current will flow when a load is connected to electrodes at both ends of the solar cell. This is the operating principal of a solar cell.

Single crystal silicon is a semiconducting material first used for fabricating solar cells since the 1980s. Currently, the relative importance of single crystal silicon in the solar cell market has considerably decreased, but single crystal silicon is still widely used in the market, particularly in the field of large-scale solar power generation systems. The reason is that the conversion efficiency of a solar cell formed of single crystal silicon is higher than that of a solar cell formed of other materials. However, since the price of single crystal silicon is still high, methods of reducing costs by using low-quality silicon, by means of mass production, and by improving fabrication processes have been attempted and studied. Since a polycrystal silicon solar cell uses a low-quality silicon wafer as a raw material, its conversion efficiency is lower than that of a single crystal silicon solar cell. However, since the price of a polycrystal silicon solar cell is low, its major fields of application include systems for homes and the like.

Since solar cells are formed of single crystal and polycrystal silicon in bulk form as a raw material, raw material costs are high and processing itself is complex, and thus there may be limits for reducing costs. As a way to resolve such limitations, a technique for innovatively reducing the thickness of a substrate and a technique for depositing a solar cell in thin film form on a low-cost substrate such as glass have received attention. This is because mass production of solar cells is possible using a lower-cost method when a typical thin film process is used.

The very first thin film solar cell developed was an amorphous silicon thin film solar cell which may be fabricated to a thickness corresponding to about 1/100 that of a typical crystalline silicon solar cell. However, its conversion efficiency may be lower than that of a crystalline silicon solar cell and particularly, the conversion efficiency may rapidly decrease when the amorphous silicon thin film solar cell is exposed to initial light. Therefore, amorphous silicon thin film solar cells may not be used for large-scale power generation systems and have been mainly used as a power source for small household appliances such as clocks, radios, and toys. However, some amorphous silicon thin film solar cells have recently begun to be used for power generation systems due to the development of multijunction amorphous silicon solar cells capable of minimizing the initial degradation phenomenon as well as having improved conversion efficiency.

A thin film solar cell that appeared thereafter was formed of a CdTe-based or CuInSe₂-based compound semiconductor as a raw material. The foregoing thin film solar cell has a conversion efficiency higher than that of an amorphous silicon solar cell and also has relatively high stability, e.g., the initial degradation phenomenon is absent. Therefore, CdTe-based compound semiconductor thin film solar cells are currently under demonstration testing for use in large-scale power generation systems.

The CuInSe₂-based compound semiconductor thin film solar cell has set a record for the highest conversion efficiency among thin film solar cells formed in a laboratory, but the CuInSe₂-based compound semiconductor thin film solar cell is in a pilot production stage and has not reached a mass production stage yet.

It is expected that a great deal of research and development is further needed before the foregoing thin film solar cells are used for a power generation system.

### DISCLOSURE OF THE INVENTION

### Technical Problem

The present invention provides high-efficiency tandem-type compound semiconductor solar cells capable of absorbing light having various wavelengths.

The present invention also provides a method of fabricating high-efficiency tandem-type compound semiconductor solar cells capable of absorbing light having various wavelengths.

The present invention is not limited to the aforesaid, and other features of the present invention not described herein will be clearly understood by those skilled in the art from descriptions below.

### Technical Solution

Embodiments of the present invention provide tandem-type compound semiconductor solar cells. The solar cells may include a transparent substrate, and a plurality of solar cell layers provided on at least one surface of the transparent substrate and each including a window layer and a light absorbing layer. The light absorbing layer may include CIGS (Cu(InGa)Se₂) nanoparticles, and the light absorbing layers included in the plurality of solar cell layers may have different bandgaps due to different Ga (gallium) contents.

In some embodiments, the CIGS nanoparticles may be formed by a method selected from the group consisting of a pulse laser ablation method, a vapor-liquid-solid method, a vapor-solid method, a solution method, and a chemical vapor deposition method.

In other embodiments, the bandgap of the light absorbing layer may be controlled by composition, size, and formation temperature of the CIGS nanoparticles.

In still other embodiments, the light absorbing layer may include a plurality of regions having different bandgaps because the CIGS nanoparticles have different thicknesses or sizes.

In even other embodiments, the transparent substrate may include soda-lime glass or Corning glass.

In yet other embodiments, the transparent substrate may further include a back electrode.

In further embodiments, the tandem-type compound semiconductor solar cell may further include an additional transparent substrate provided between the plurality of solar cell layers.

In still further embodiments, the window layer may include a metal oxide doped with a p-type or n-type impurity. The metal oxide may include at least one material selected from the group consisting of zinc oxide, gallium oxide, aluminum oxide, indium oxide, lead oxide, copper oxide, titanium oxide, tin oxide, iron oxide, and indium tin oxide.

In even further embodiments, the tandem-type compound semiconductor solar cell may further include a buffer layer provided between the window layer and the light absorbing layer for relieving difference in interlayer bandgap energies and lattice constants thereof.

In yet further embodiments, the tandem-type compound semiconductor solar cell may further include a grid electrode provided on the plurality of solar cell layers facing the transparent substrate.

In much further embodiments, the tandem-type compound semiconductor solar cell may further include an anti-reflective layer provided on the plurality of solar cell layers facing the transparent substrate.

In still much further embodiments, the tandem-type compound semiconductor solar cell may further include a transparent conductive oxide layer provided between the light absorbing layer and the grid electrode or the light absorbing layer and the anti-reflective layer.

In even much further embodiments, the light absorbing layer of a lowermost solar cell layer among the plurality of solar cell layers may include a CIGS thin film.

In other embodiments of the present invention, methods of fabricating a tandem-type compound semiconductor solar cell are provided. The methods may include forming a plurality of solar cell layers on at least one surface of a transparent substrate, each of the solar cell layers including a window layer and a light absorbing layer including CIGS (Cu(InGa)Se₂) nanoparticles. The light absorbing layers included in the plurality of solar cell layers may have different bandgaps due to different Ga (gallium) contents.

In some embodiments, the CIGS nanoparticles may be formed by a method selected from the group consisting of a pulse laser ablation method, a vapor-liquid-solid method, a vapor-solid method, a solution method, and a chemical vapor deposition method.

In other embodiments, the bandgap of the light absorbing layer may be controlled by composition, size, and formation temperature of the CIGS nanoparticles.

In still other embodiments, the light absorbing layer may be formed to include a plurality of regions having different bandgaps because the CIGS nanoparticles have different thicknesses or sizes.

In even other embodiments, the transparent substrate may include soda-lime glass or Corning glass.

In yet other embodiments, the method may further include forming a back electrode.

In further embodiments, the method may further include forming an additional transparent substrate between the plurality of solar cell layers.

In still further embodiments, the window layer may be formed of a metal oxide doped with a p-type or n-type impurity. The metal oxide may include at least one material selected from the group consisting of zinc oxide, gallium oxide, aluminum oxide, indium oxide, lead oxide, copper oxide, titanium oxide, tin oxide, iron oxide, and indium tin oxide.

In even further embodiments, the method may further include forming a buffer layer between the window layer and the light absorbing layer to relieve difference in interlayer bandgap energies and lattice constants thereof.

In yet further embodiments, the method may further include forming a grid electrode on the plurality of solar cell layers facing the transparent substrate.

In much further embodiments, the method may further include forming an anti-reflective layer on the plurality of solar cell layers facing the transparent substrate.

In still further embodiments, the grid electrode and the anti-reflective layer may be formed at the same time.

In even much further embodiments, the method may further include forming a transparent conductive oxide layer between the light absorbing layer and the grid electrode or the light absorbing layer and the anti-reflective layer.

In yet much further embodiments, the light absorbing layer of a lowermost solar cell layer among the plurality of solar cell layers may be formed of a CIGS thin film.

### Advantageous Effects

According to an embodiment of the present invention, a plurality of light absorbing layers is composed of Cu(InGa)Se₂ (CIGS) nanoparticles having different bandgaps and thus a solar cell may absorb light having various wavelengths. Therefore, a high-efficiency solar cell may be provided.

Also, the light absorbing layer is composed of the CIGS nanoparticles to have semi-transparent characteristics and thus transmission and absorption of light may be facilitated. Therefore, a high-efficiency solar cell may be provided.

In addition, the light absorbing layer composed of the CIGS nanoparticles is formed by a method selected from the group consisting of pulse laser ablation method, vapor-liquid-solid method, vapor-solid method, solution method, and chemical vapor deposition method, and thus control of the composition of the CIGS nanoparticles may be facilitated. Therefore, a method of fabricating a high-efficiency solar cell may be provided.

Further, electrical properties, e.g., interface contact properties, of the light absorbing layer composed of the CIGS nanoparticles may vary according to formation temperature and thus control of the electrical properties may be facilitated. Therefore, a method of fabricating a high-efficiency solar cell may be provided.

### BRIEF DESCRIPTION OF THE DRAWINGS

FIG. 1 is a cross-sectional view illustrating a tandem-type compound semiconductor solar cell according to an embodiment of the present invention;

FIGS. 2 through 5 are scanning electron micrographs showing light absorbing layers of the tandem-type compound semiconductor solar cell according to the embodiment of the present invention;

FIG. 6 is a graph showing bandgap characteristics of the light absorbing layer of the tandem-type compound semiconductor solar cell according to the embodiment of the present invention;

FIG. 7 is a cross-sectional view illustrating a tandem-type compound semiconductor solar cell according to another embodiment of the present invention; and

FIGS. 8 through 17 are cross-sectional views illustrating a method of fabricating a tandem-type compound semiconductor solar cell according to an embodiment of the present invention.

### MODE FOR CARRYING OUT THE INVENTION

Hereinafter, preferred embodiments of the present invention will be described in more detail with reference to the accompanying drawings. Advantages and features of the present invention, and implementation methods thereof will be clarified through following embodiments described with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Further, the present invention is only defined by scopes of claims. Like reference numerals refer to like elements throughout.

In the following description, the technical terms are used only for explaining a specific exemplary embodiment while not limiting the present invention. The terms of a singular form may include plural forms unless referred to the contrary. The meaning of “comprises” and/or “comprising” specifies a property, a region, a fixed number, a step, a process, an element and/or a component but does not exclude other properties, regions, fixed numbers, steps, processes, elements and/or components. Since preferred embodiments are provided below, the order of the reference numerals given in the description is not limited thereto. Further, in the specification, it will be understood that when a layer (or film) is referred to as being ‘on’ another layer or substrate, it can be directly on the other layer or substrate, or intervening layers may also be present.

Additionally, the embodiment in the detailed description will be described with sectional views as ideal exemplary views of the present invention. In the figures, the dimensions of layers and regions are exaggerated for clarity of illustration. Accordingly, shapes of the exemplary views may be modified according to manufacturing techniques and/or allowable errors. Therefore, the embodiments of the present invention are not limited to the specific shape illustrated in the exemplary views, but may include other shapes that may be created according to manufacturing processes. For example, an etch region illustrated with right angles may be rounded or be configured with a predetermined curvature. Therefore, areas exemplified in the drawings have general properties, and are used to illustrate specific shapes of certain regions. Thus, this should not be construed as limited to the scope of the present invention.

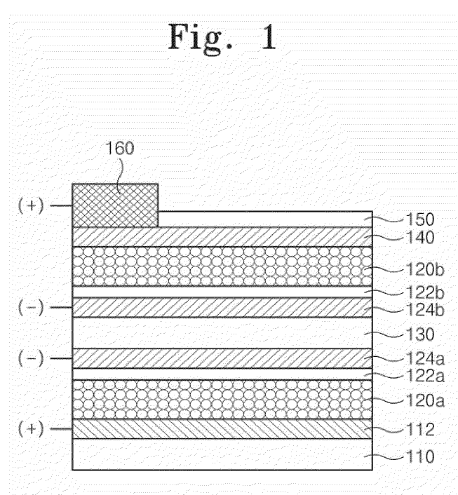

FIG. 1 is a cross-sectional view illustrating a tandem-type compound semiconductor solar cell according to an embodiment of the present invention.

Referring to FIG. 1, the tandem-type compound semiconductor solar cell includes a transparent substrate 110 and a plurality of solar cell layers provided on at least one surface of the transparent substrate 110. The plurality of solar cell layers respectively include window layers 124a and 124b and light absorbing layers 120a and 120b.

The plurality of solar cell layers may be separately provided on an upper surface or lower surface of the transparent substrate 110, or may be provided in a stacked configuration on the upper surface or lower surface of the transparent substrate 110. Also, the plurality of solar cell layers may be provided on both upper and lower surfaces of the transparent substrate 110. In addition, the window layers 124a and 124b and the light absorbing layers 120a and 120b constituting the solar cell layers may also be provided in a plurality of layers.

An additional transparent substrate 130 may be further provided between the plurality of solar cell layers. The additional transparent substrate 130 may insulate between the stacked plurality of solar cell layers.

According to a stacking sequence of the window layers 124a and 124b and the light absorbing layers 120a and 120b constituting the solar cell layers, the tandem-type compound semiconductor solar cell is classified as superstrate type and substrate type. A tandem-type compound semiconductor solar cell having a solar cell layer stacked in a sequence of the window layers 124a and 124b and the light absorbing layers 120a and 120b on the transparent substrate 110 may be a superstrate type, and a tandem-type compound semiconductor solar cell having a solar cell layer stacked in a sequence of the light absorbing layers 120a and 120b and the window layers 124a and 124b on the transparent substrate 110 may be a substrate type. In general, the substrate type has photoelectric conversion efficiency higher than that of the superstrate type.

The transparent substrate 110 may include soda-lime glass or Corning glass. The transparent substrate 110 may further include a back electrode 112. The back electrode 112 may include at least one material selected from the group consisting of molybdenum (Mo), aluminum (Al), silver (Ag), gold (Au), platinum (Pt), copper (Cu), and nickel (Ni). The back electrode 112 may be an electrode for applying a load to the solar cell layers. Also, the back electrode 112 may play a role in reflecting light absorbed in the light absorbing layers 120a and 120b so as not to escape outside.

The window layers 124a and 124b may include metal oxide doped with a p-type or n-type impurity. The metal oxide may include at least one material selected from the group consisting of zinc oxide (ZnO), gallium oxide (Ga₂O₃), aluminum oxide (Al₂O₃), indium oxide (In₂O₃), lead oxide (PbO), copper oxide (CuO), titanium oxide (TiO₂), tin oxide (SnO₂), iron oxide (FeO), and indium tin oxide (ITO). Since the window layers 124a and 124b include the metal oxide, the window layers 124a and 124b may be used as an electrode for applying a load to the solar cell layers.

The light absorbing layers 120a and 120b may include Cu(InGa)Se₂ (CIGS) nanoparticles. The CIGS nanoparticles may be formed by a method selected from the group consisting of pulse laser ablation method, vapor-liquid-solid method, vapor-solid method, solution method, and chemical vapor deposition (CVD) method. Since the light absorbing layers 120a and 120b include the CIGS nanoparticles, bandgaps of the light absorbing layers 120a and 120b may be controlled by means of composition, size, and formation temperature of the CIGS nanoparticles. As a result, the respective light absorbing layers 120a and 120b of the plurality of solar cell layers may have different bandgaps due to different gallium (Ga) contents. Also, when the light absorbing layers 120a and 120b are composed of nanoparticles, photoelectric conversion efficiency may be improved by a quantum effect.

Further, the light absorbing layers 120a and 120b may include a plurality of regions having different bandgaps because the CIGS nanoparticles have different thicknesses or sizes from one another. Therefore, the single light absorbing layer 120a or 120b may absorb light having various wavelengths.

Buffer layers 122a and 122b relieving differences in interlayer bandgap energies and lattice constants may be provided between the window layers 124a and 124b and the light absorbing layers 120a and 120b. The buffer layers 122a and 122b may include cadmium sulfide (CdS), zinc sulfide (ZnS), or indium oxide.

An anti-reflective layer 150 and a grid electrode 160 may be provided on the plurality of solar cell layers facing the transparent substrate 110. The anti-reflective layer 150 may include magnesium fluoride (MgF₂). The anti-reflective layer 150 may minimize loss of incident light by minimizing the reflection of the incident light. The grid electrode 160 may include aluminum or a nickel aluminum alloy (Ni/Al). The grid electrode 160 may be an electrode for applying a load to the solar cell layers.

A transparent conductive oxide (TCO) layer 140 may be provided between the uppermost light absorbing layer 120b and the grid electrode 160 or the uppermost light absorbing layer 120b and the anti-reflective layer 150. Since the light absorbing layers 120a and 120b including the CIGS nanoparticles may not form a good ohmic contact with metals having low work functions such as aluminum or nickel, the transparent conductive oxide layer 140 may be used for improving ohmic contact characteristics between the grid electrode 160 including metal having low work function and the uppermost light absorbing layer 120b. The transparent conductive oxide layer 140 may include zinc-based oxide, indium-based oxide, or tin-based oxide.

The light absorbing layer 120a of a lowermost solar cell layer among the plurality of solar cell layers may be composed of a CIGS thin film. As a result, stability of the entire tandem-type compound semiconductor solar cell may be obtained and a light absorbing region may become wide.

Since the tandem-type compound semiconductor solar cell according to the embodiment of the present invention includes the plurality of light absorbing layers 120a and 120b composed of the CIGS nanoparticles formed to have different bandgaps, the tandem-type compound semiconductor solar cell may absorb light having various wavelengths. Also, since the light absorbing layers 120a and 120b composed of the CIGS nanoparticles are semi-transparent, transmission and absorption of light may be facilitated. In addition, since the light absorbing layers 120a and 120b composed of the CIGS nanoparticles are formed by a method selected from the group consisting of pulse laser ablation method, vapor-liquid-solid method, and vapor-solid method, control of the composition of the CIGS nanoparticles may be facilitated. In addition, since electrical properties, e.g., interface contact properties, of the light absorbing layers 120a and 120b composed of the CIGS nanoparticles may vary according to formation temperature, control of the electrical properties may be facilitated. Therefore, a solar cell having higher conversion efficiency by absorption of light having various wavelengths may be provided.

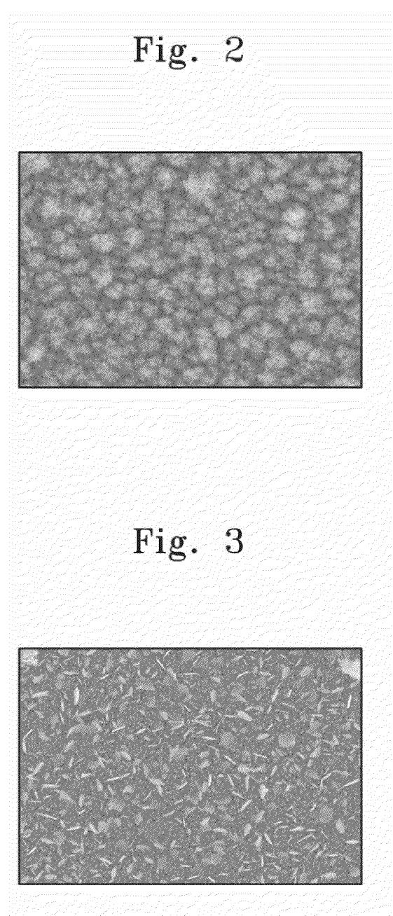

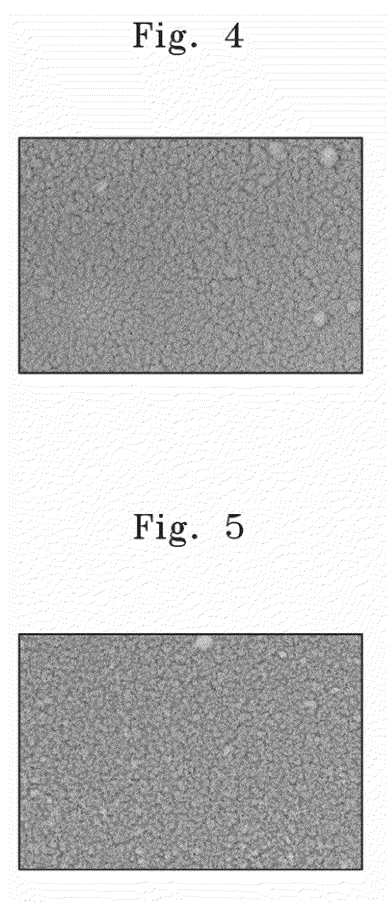

FIGS. 2 through 5 are scanning electron micrographs showing light absorbing layers of the tandem-type compound semiconductor solar cell according to the embodiment of the present invention.

Referring to FIGS. 2 through 5, the scanning electron micrographs show states of the light absorbing layer (see 120a or 120b in FIG. 1) composed of CIGS nanoparticles formed on an indium tin oxide substrate according to formation temperatures.

FIGS. 2, 3, 4, and 5 are images of the CIGS nanoparticles formed at room temperature, 300° C., 400° C., and 500° C., respectively. It may be understood that shapes and colors of the CIGS nanoparticles are changed according to the formation temperatures. It may be understood that the higher the formation temperature is, the smaller the size of the CIGS nanoparticles is. However, all the CIGS nanoparticles have semi-transparent characteristics despite the formation temperature.

The following Table 1 shows compositions of the CIGS nanoparticles according to the formation temperatures.

TABLE 1

| Formation | | | |
|---|---|---|---|
| temperature | Cu/(In + Ga) | Cu/In | Ga(Ga + In) |
| Room temperature | 1.35 | 1.35 | — |
| 300° C. | 0.53 | 0.53 | 0.025 |
| 400° C. | 0.69 | 0.71 | 0.021 |
| 500° C. | 0.68 | 0.68 | 0.006 |

As shown in Table 1, it may be understood that the size of the CIGS nanoparticles may increase as a content of Cu increases.

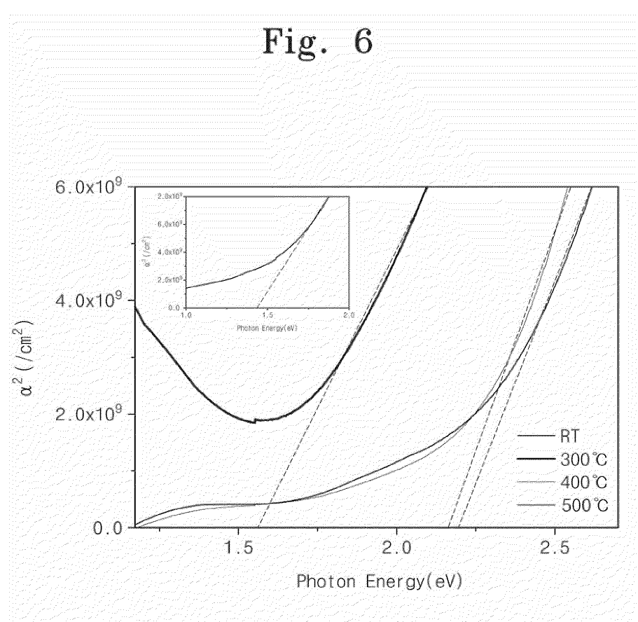

FIG. 6 is a graph showing bandgap characteristics of the light absorbing layer of the tandem-type compound semiconductor solar cell according to the embodiment of the present invention.

Referring to FIG. 6, the graph shows optically measured bandgap characteristics of the light absorbing layer (see 120a or 120b in FIG. 1) composed of the CIGS nanoparticles formed on the indium tin oxide substrate according to formation temperatures

It may be understood that the light absorbing layers composed of the CIGS nanoparticles formed at room temperature, 300° C., 400° C., and 500° C. have a bandgap of 1.43 eV, 1.56 eV, 2.16 eV, and 2.2 eV, respectively. Thus, it may be understood that the CIGS nanoparticles have different bandgaps according to the composition, size, and formation temperature thereof. The CIGS nanoparticles have characteristics in which the bandgap increases as a content of Ga increases and the size decreases.

As a result, when the light absorbing layers composed of the CIGS nanoparticles having different bandgaps are used in a single solar cell, light having various wavelengths may be absorbed. Therefore, conversion efficiency of the solar cell may further increase.

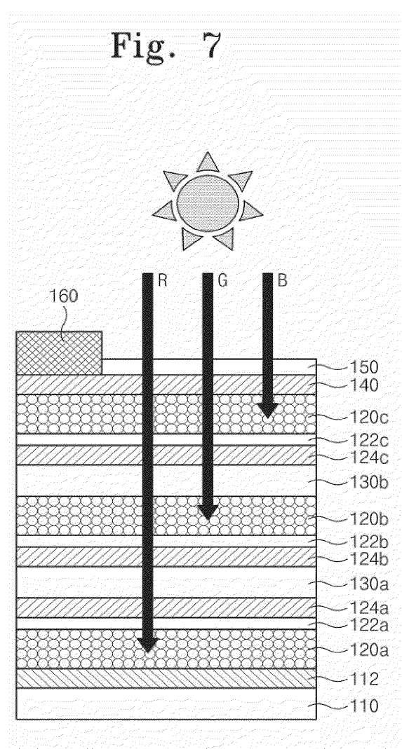

FIG. 7 is a cross-sectional view illustrating a tandem-type compound semiconductor solar cell according to another embodiment of the present invention.

Referring to FIG. 7, the tandem-type compound semiconductor solar cell includes a transparent substrate 110, and three solar cell layers composed of window layers 124a, 124b and 124c and light absorbing layers 120a, 120b and 120c provided on at least one surface of the transparent substrate 110.

The three solar cell layers may be provided in a stacked configuration on an upper surface of the transparent substrate 110. Also, the window layers 124a, 124b and 124c and the light absorbing layers 120a, 120b and 120c constituting the solar cell layers may be provided in a plurality of layers.

When the three solar cell layers are provided in the stacked configuration, additional transparent substrates 130a and 130b may be further provided between the three solar cell layers. The additional transparent substrates 130a and 130b may insulate between the stacked three solar cell layers.

The transparent substrate 110 may further include a back electrode 112. The back electrode 112 may be an electrode for applying a load to the solar cell layers. Also, the back electrode 112 may play a role in reflecting light absorbed in the light absorbing layers 120a, 120b and 120c so as not to escape outside.

The window layers 124a, 124b and 124c may include metal oxide doped with a p-type or n-type impurity. Since the window layers 124a, 124b and 124c include the metal oxide, the window layers 124a, 124b and 124c may be used as an electrode for applying a load to the solar cell layers.

The light absorbing layers 120a, 120b and 120c may include Cu(InGa)Se₂ (CIGS) nanoparticles. Since the light absorbing layers 120a, 120b and 120c include the CIGS nanoparticles, bandgaps of the light absorbing layers 120a, 120b and 120c may be controlled by means of composition, size, and formation temperature of the CIGS nanoparticles. As a result, the respective light absorbing layers 120a, 120b and 120c of the three solar cell layers may have different bandgaps due to different Ga contents.

The lower light absorbing layer 120a may absorb light R having a wavelength near a red band, the intermediate light absorbing layer 120b may absorb light G having a wavelength near a green band, and the upper light absorbing layer 120c may absorb light B having a wavelength near a blue band. The reason for this is that possibility for the light R having a wavelength near the red band with a relatively long wavelength to arrive at the lower light absorbing layer 120a is relatively high and possibility for the light B having a wavelength near the blue band with a relatively short wavelength to arrive at the lower light absorbing layer 120a is relatively low. The light absorbing layers 120a, 120b and 120c able to absorb light having a wavelength near an appropriate band according to the length of the wavelength are properly arranged and thus conversion efficiency of the tandem-type compound semiconductor solar cell may be further increased.

Also, the light absorbing layers 120a, 120b and 120c may include a plurality of regions having different bandgaps because the CIGS nanoparticles have different thicknesses or sizes from one another. Therefore, the single light absorbing layer 120a, 120b or 120c may absorb light having various wavelengths.

Buffer layers 122a, 122b and 122c relieving differences in interlayer bandgap energies and lattice constants may be provided between the window layers 124a, 124b and 124c and the light absorbing layers 120a, 120b and 120c.

An anti-reflective layer 150 and a grid electrode 160 may be provided on the plurality of solar cell layers facing the transparent substrate 110. The anti-reflective layer 150 may minimize loss of incident light by minimizing the reflection of the incident light. The grid electrode 160 may be an electrode for applying a load to the solar cell layers.

A transparent conductive oxide layer 140 may be provided between the uppermost light absorbing layer 120c and the grid electrode 160 or the uppermost light absorbing layer 120c and the anti-reflective layer 150. Since the light absorbing layers 120a, 120b and 120c including the CIGS nanoparticles may not form a good ohmic contact with metals having low work functions such as aluminum or nickel, the transparent conductive oxide layer 140 may be used for improving ohmic contact characteristics between the grid electrode 160 including metal having low work function and the uppermost light absorbing layer 120c.

The light absorbing layer 120a of a lowermost solar cell layer among the three solar cell layers may be composed of a CIGS thin film. As a result, stability of the entire tandem-type compound semiconductor solar cell may be obtained and a light absorbing region may become wide.

Since the tandem-type compound semiconductor solar cell according to the embodiment of the present invention includes the three light absorbing layers 120a, 120b and 120c composed of the CIGS nanoparticles formed to have different bandgaps, the tandem-type compound semiconductor solar cell may absorb light having various wavelengths over the red band, green band, and blue band. Also, since the light absorbing layers 120a, 120b and 120c composed of the CIGS nanoparticles are semi-transparent, transmission and absorption of light may be facilitated. In addition, since the light absorbing layers 120a, 120b and 120c composed of the CIGS nanoparticles are formed by a method selected from the group consisting of pulse laser ablation method, vapor-liquid-solid method, and vapor-solid method, control of the composition of the CIGS nanoparticles may be facilitated. In addition, since electrical properties, e.g., interface contact properties, of the light absorbing layers 120a, 120b and 120c composed of the CIGS nanoparticles may vary according to formation temperature, control of the electrical properties may be facilitated. As a result, a solar cell having higher conversion efficiency by absorption of light having various wavelengths may be provided.

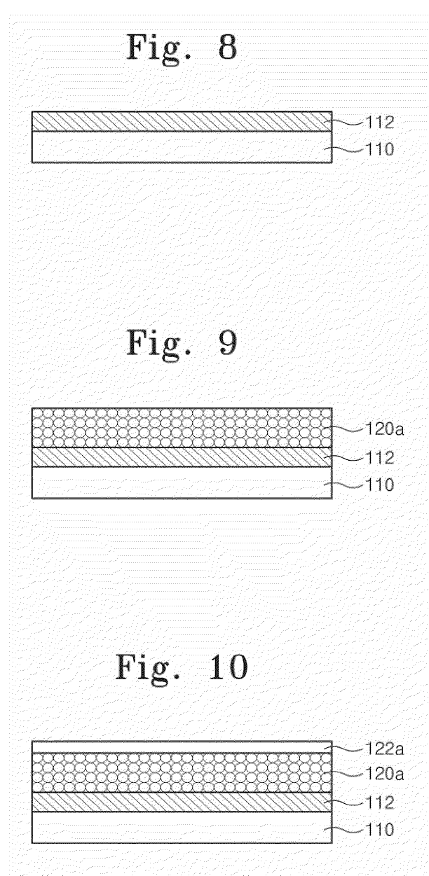

FIGS. 8 through 17 are cross-sectional views illustrating a method of fabricating a tandem-type compound semiconductor solar cell according to an embodiment of the present invention.

Referring to FIG. 8, a back electrode 112 is disposed on a transparent substrate 110. The transparent substrate 110 may include soda-lime glass or Corning glass. The back electrode 112 may include at least one material selected from the group consisting of molybdenum, aluminum, silver, gold, platinum, copper, and nickel. The back electrode 112 may be an electrode for applying a load to the solar cell layers. Also, the back electrode 112 may play a role in reflecting light absorbed in the light absorbing layers (see 120a and 120b in FIG. 17) so as not to escape outside.

Referring to FIG. 9, a first light absorbing layer 120a is disposed on the back electrode 112. The first light absorbing layer 120a may include CIGS nanoparticles. The CIGS nanoparticles may be formed by a method selected from the group consisting of pulse laser ablation method, vapor-liquid-solid method, vapor-solid method, solution method, and chemical vapor deposition method.

Since the first light absorbing layer 120a includes the CIGS nanoparticles, a bandgap of the first light absorbing layer 120a may be controlled by means of composition, size, and formation temperature of the CIGS nanoparticles. For example, the first light absorbing layer 120a may be designed to absorb light having a wavelength near the red band by being formed to have relatively high Ga content and small size. Also, the first light absorbing layers 120a may include a plurality of regions having different bandgaps because the CIGS nanoparticles have different thicknesses or sizes from one another. Therefore, the first light absorbing layer 120a may absorb light having various wavelengths.

Alternatively, the first light absorbing layer 120a may be composed of a CIGS thin film. As a result, stability of the entire tandem-type compound semiconductor solar cell may be obtained and a light absorbing region may become wide.

Referring to FIGS. 10 and 11, a first buffer layer 122a and a first window layer 124a are sequentially disposed on the first light absorbing layer 120a. The first buffer layer 122a may include cadmium sulfide, zinc sulfide, or indium oxide. The first buffer layer 122a may relieve differences in interlayer bandgap energies and lattice constants between the first light absorbing layer 120a and the first window layer 124a. As a result, conversion efficiency of a first solar cell layer composed of the first light absorbing layer 120a, the first buffer layer 122a, and the first window layer 124a may be further increased.

The first window layer 124a may include metal oxide doped with a p-type or n-type impurity. The metal oxide may include at least one material selected from the group consisting of zinc oxide, gallium oxide, aluminum oxide, indium oxide, lead oxide, copper oxide, titanium oxide, tin oxide, iron oxide, and indium tin oxide. Since the first window layer 124a includes the metal oxide, the first window layer 124a may be used as an electrode for applying a load to the first solar cell layer.

Referring to FIG. 12, an additional transparent substrate 130 is disposed on the first solar cell layer. The additional transparent substrate 130 may be used for insulating between the first solar cell layer and a second solar cell layer which will be stacked later.

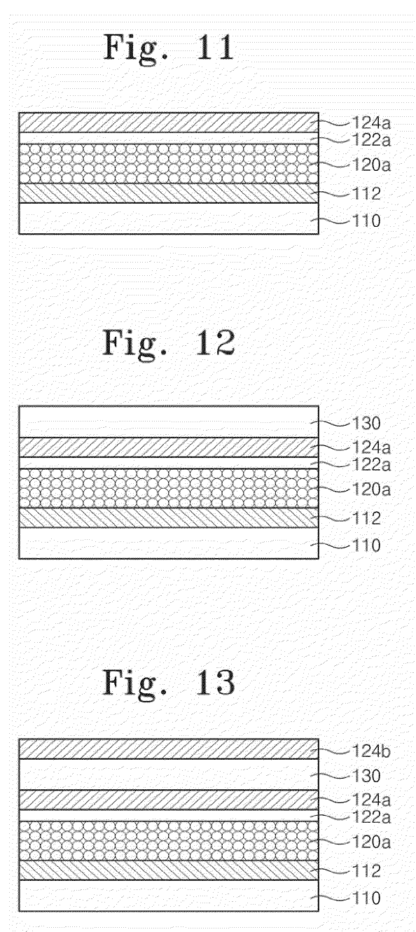

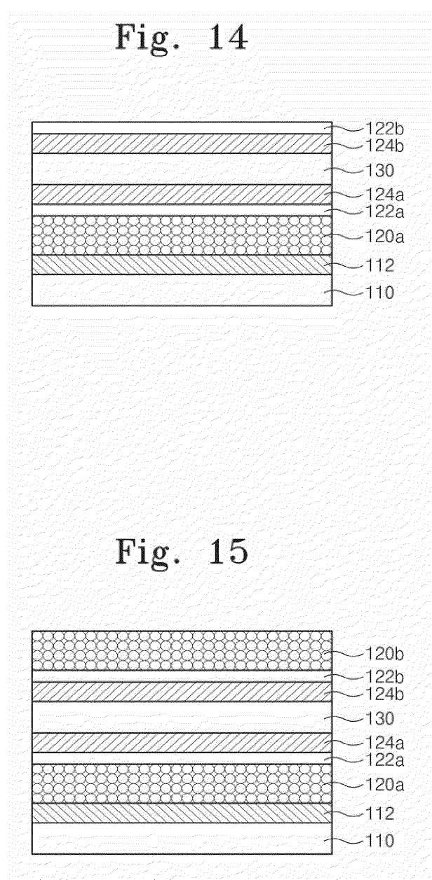

Referring to FIG. 13, a second window layer 124b is disposed on the additional transparent substrate 130. The second window layer 124b may include metal oxide doped with a p-type or n-type impurity. The metal oxide may include at least one material selected from the group consisting of zinc oxide, gallium oxide, aluminum oxide, indium oxide, lead oxide, copper oxide, titanium oxide, tin oxide, iron oxide, and indium tin oxide. Since the second window layer 124b includes the metal oxide, the second window layer 124b may be used as an electrode for applying a load to the second solar cell layer composed together of a second buffer layer (see 122b in FIG. 14) and a second light absorbing layer (see 120b in FIG. 15) which will be disposed later.

Referring to FIGS. 14 and 15, the second buffer layer 122b and the second light absorbing layer 120b are sequentially disposed on the second window layer 124b. The second buffer layer 122b may include cadmium sulfide, zinc sulfide, or indium oxide. The second buffer layer 122b may relieve differences in interlayer bandgap energies and lattice constants between the second window layer 124b and the second light absorbing layer 120b. As a result, conversion efficiency of the second solar cell layer composed of the second window layer 124b, the second buffer layer 122b, and the second light absorbing layer 120b may be further increased.

The second light absorbing layer 120b may include CIGS nanoparticles. The CIGS nanoparticles may be formed by a method selected from the group consisting of pulse laser ablation method, vapor-liquid-solid method, vapor-solid method, solution method, and chemical vapor deposition method.

Since the second light absorbing layer 120b includes the CIGS nanoparticles, a bandgap of the second light absorbing layer 120b may be controlled by means of composition, size, and formation temperature of the CIGS nanoparticles. For example, the second light absorbing layer 120b may be designed to absorb light having a wavelength near the blue band by being formed to have relatively low Ga content and large size. Also, the second light absorbing layers 120b may include a plurality of regions having different bandgaps because the CIGS nanoparticles have different thicknesses or sizes from one another. Therefore, the second light absorbing layer 120b may absorb light having various wavelengths.

Although not shown in the drawings, a third solar cell layer including a third light absorbing layer having a bandgap different from those of the first and second solar cell layers may further be disposed on the second solar cell layer. The third light absorbing layer may be designed to absorb light having a wavelength near a different color band.

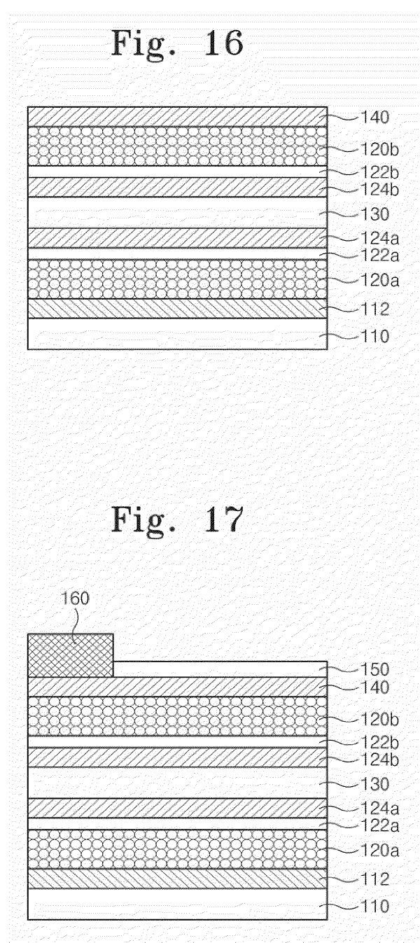

Referring to FIG. 16, a transparent conductive oxide layer 140 is disposed on the plurality of solar cell layers. The transparent conductive oxide layer 140 may include zinc-based oxide, indium-based oxide, or tin-based oxide. The transparent conductive oxide layer 140 may be used for improving ohmic contact characteristics between a grid electrode (see 160 in FIG. 17) which will be disposed later and the uppermost second light absorbing layer 120b. The reason for this is that the second light absorbing layer 120b including the CIGS nanoparticles may not form a good ohmic contact with metals having low work functions such as aluminum or nickel.

Referring to FIG. 17, an anti-reflective layer 150 and a grid electrode 160 may be disposed on the transparent conductive oxide layer 140. The anti-reflective layer 150 may include magnesium fluoride. The anti-reflective layer 150 may be used for minimizing loss of incident light by minimizing the reflection of the incident light. The grid electrode 160 may include aluminum or a nickel aluminum alloy. The grid electrode 160 may be an electrode for applying a load to the solar cell layers. The anti-reflective layer 150 and the grid electrode 160 may be sequentially disposed or may be disposed at the same time.

Since the tandem-type compound semiconductor solar cell according to the embodiment of the present invention includes the plurality of light absorbing layers 120a and 120b composed of the CIGS nanoparticles formed to have different bandgaps, the tandem-type compound semiconductor solar cell may absorb light having various wavelengths. Also, since the light absorbing layers 120a and 120b composed of the CIGS nanoparticles are semi-transparent, transmission and absorption of light may be facilitated. In addition, since the light absorbing layers 120a and 120b composed of the CIGS nanoparticles are formed by a method selected from the group consisting of pulse laser ablation method, vapor-liquid-solid method, vapor-solid method, solution method, and chemical vapor deposition method, control of the composition of the CIGS nanoparticles may be facilitated. In addition, since electrical properties, e.g., interface contact properties, of the light absorbing layers 120a and 120b composed of the CIGS nanoparticles may vary according to formation temperature, control of the electrical properties may be facilitated. Therefore, a solar cell having higher conversion efficiency by absorption of light having various wavelengths may be provided.

While preferred embodiments of the present invention has been particularly shown and described with reference to the accompanying drawings, it will be understood by those skilled in the art that various changes in form and details may be made therein without departing from the spirit and scope of the invention as defined by the appended claims. Therefore, the preferred embodiments should be considered in descriptive sense only and not for purposes of limitation.

### INDUSTRIAL APPLICABILITY

The present invention may be used in a solar energy generation device or system for generating power.

1. A tandem-type compound semiconductor solar cell comprising:
a transparent substrate; and
a plurality of solar cell layers provided on at least one surface of the transparent substrate and each including a window layer and a light absorbing layer,
wherein the light absorbing layer includes CIGS (Cu(InGa)Se₂) nanoparticles, and
the light absorbing layers of the plurality of solar cell layers have different bandgaps due to different Ga (gallium) contents.

2. The tandem-type compound semiconductor solar cell of claim 1, wherein the CIGS nanoparticles are formed by a method selected from the group consisting of a pulse laser ablation method, a vapor-liquid-solid method, a vapor-solid method, a solution method, and a chemical vapor deposition method.

3. The tandem-type compound semiconductor solar cell of claim 1, wherein the bandgap of the light absorbing layer is controlled by composition, size, and formation temperature of the CIGS nanoparticles.

4. The tandem-type compound semiconductor solar cell of claim 1, wherein the light absorbing layer comprises a plurality of regions having different bandgaps because the CIGS nanoparticles have different thicknesses or sizes.

5. The tandem-type compound semiconductor solar cell of claim 1, wherein the transparent substrate comprises soda-lime glass or Corning glass.

6. The tandem-type compound semiconductor solar cell of claim 1, wherein the transparent substrate further comprises a back electrode.

7. The tandem-type compound semiconductor solar cell of claim 1, further comprising an additional transparent substrate between the plurality of solar cell layers.

8. The tandem-type compound semiconductor solar cell of claim 1, wherein the window layer comprises a metal oxide doped with a p-type or n-type impurity.

9. The tandem-type compound semiconductor solar cell of claim 8, wherein the metal oxide comprises at least one material selected from the group consisting of zinc oxide, gallium oxide, aluminum oxide, indium oxide, lead oxide, copper oxide, titanium oxide, tin oxide, iron oxide, and indium tin oxide.

10. The tandem-type compound semiconductor solar cell of claim 1, further comprising a buffer layer provided between the window layer and the light absorbing layer for relieving difference in interlayer bandgap energies and lattice constants thereof.

11. The tandem-type compound semiconductor solar cell of claim 1, further comprising a grid electrode provided on the plurality of solar cell layers facing the transparent substrate.

12. The tandem-type compound semiconductor solar cell of claim 1, further comprising an anti-reflective layer provided on the plurality of solar cell layers facing the transparent substrate.

13. The tandem-type compound semiconductor solar cell of claim 11, further comprising a transparent conductive oxide layer provided between the light absorbing layer and the grid electrode or the light absorbing layer and the anti-reflective layer.

14. The tandem-type compound semiconductor solar cell of claim 1, wherein the light absorbing layer of a lowermost solar cell layer among the plurality of solar cell layers comprises a CIGS thin film.

15. A method of fabricating a tandem-type compound semiconductor solar cell, the method comprising forming a plurality of solar cell layers on at least one surface of a transparent substrate, each of the solar cell layers including a window layer and a light absorbing layer including CIGS (Cu(InGa)Se2) nanoparticles,
wherein the light absorbing layers of the plurality of solar cell layers have different bandgaps due to different Ga (gallium) contents.

16. The method of claim 15, wherein the CIGS nanoparticles are formed by a method selected from the group consisting of a pulse laser ablation method, a vapor-liquid-solid method, a vapor-solid method, a solution method, and a chemical vapor deposition method.

17. The method of claim 15, wherein the bandgap of the light absorbing layer is controlled by composition, size, and formation temperature of the CIGS nanoparticles.

18. The method of claim 15, wherein the light absorbing layer includes a plurality of regions having different bandgaps because the CIGS nanoparticles have different thicknesses or sizes.

19. The method of claim 15, wherein the transparent substrate comprises soda-lime glass or Corning glass.

20. The method of claim 15, further comprising forming a back electrode on the transparent substrate.

21. The method of claim 15, further comprising forming an additional transparent substrate between the plurality of solar cell layers.

22. The method of claim 15, wherein the window layer is formed of a metal oxide doped with a p-type or n-type impurity.

23. The method of claim 22, wherein the metal oxide comprises at least one material selected from the group consisting of zinc oxide, gallium oxide, aluminum oxide, indium oxide, lead oxide, copper oxide, titanium oxide, tin oxide, iron oxide, and indium tin oxide.

24. The method of claim 15, further comprising forming a buffer layer between the window layer and the light absorbing layer to relieve difference in interlayer bandgap energies and lattice constants thereof.

25. The method of claim 15, further comprising forming a grid electrode on the plurality of solar cell layers facing the transparent substrate.

26. The method of claim 15, further comprising forming an anti-reflective layer on the plurality of solar cell layers facing the transparent substrate.

27. The method of claim 25, wherein the grid electrode and the anti-reflective layer are fouled at the same time.

28. The method of claim 25, further comprising forming a transparent conductive oxide layer between the light absorbing layer and the grid electrode or the light absorbing layer and the anti-reflective layer.

29. The method of claim 15, wherein the light absorbing layer of a lowermost solar cell layer among the plurality of solar cell layers is formed of a CIGS thin film.
